(19) United States
(12) Patent Application Publication
(10) Pub. No.: US 2006/0261385 A1
(43) Pub. Date: Nov. 23, 2006

(54) Phase shift transparent structures for imaging devices

(75) Inventors: Jiutao Li, Boise, ID (US); Jin Li, Boise, ID (US)

Correspondence Address: DICKSTEIN SHAPIRO LLP, 1825 EYE STREET NW, Washington, DC, 20006-5403, US

(73) Assignee: Micron Technology, Inc.

(21) Appl. No.: 11/134,315

(22) Filed: May 23, 2005

(51) Int. Cl. H01L 31/062

(52) U.S. Cl. 257/292

(57) ABSTRACT

An imaging device having a pixel cell with a transparent structure capable of shifting the phase of a wavelength above pixel circuitry, thereby reducing noise within a pixel cell, and also reducing the amount of cross-talk between pixel cells.

### FIELD OF THE INVENTION

The invention relates generally to imaging devices and, more particularly to lenses used to focus light on a photosensor of a pixel cell.

### BACKGROUND OF THE INVENTION

Imaging devices, including charge coupled devices (CCD) and complementary metal oxide semiconductor (CMOS) sensors have commonly been used in photo-imaging applications. A CMOS imager circuit includes a focal plane array of pixel cells, each one of the cells including a photosensor, for example, a photogate, photoconductor or a photodiode for accumulating photo-generated charge in the specified portion of the substrate. Each pixel cell has a charge storage region, formed on or in the substrate, which is connected to the gate of an output transistor that is part of a readout circuit. The charge storage region may be constructed as a floating diffusion region. In some imager circuits, each pixel may include at least one electronic device such as a transistor for transferring charge from the photosensor to the storage region and one device, also typically a transistor, for resetting the storage region to a predetermined charge level prior to charge transference.

In a CMOS imager, the active elements of a pixel cell perform the functions of: (1) photon to charge conversion; (2) accumulation of image charge; (3) resetting the storage region to a known state; (4) transfer of charge to the storage region; (5) selection of a pixel for readout; and (6) output and amplification of signals representing pixel reset level and pixel charge. Photo charge may be amplified when it moves from the initial charge accumulation region to the storage region. The charge at the storage region is typically converted to a pixel output voltage by a source follower output transistor.

Exemplary CMOS imaging circuits, processing steps thereof, and detailed descriptions of the functions of various CMOS elements of an imaging circuit are described, for example, in U.S. Pat. No. 6,140,630; U.S. Pat. No. 6,376,868; U.S. Pat. No. 6,310,366; U.S. Pat. No. 6,326,652; U.S. Pat. No. 6,204,524; U.S. Pat. No. 6,333,205; and U.S. Pat. No. 6,852,591, all of which are assigned to Micron Technology, Inc. The disclosures of each of the forgoing are hereby incorporated by reference in their entirety.

FIG. 1 illustrates a partial schematic cross-sectional representation of a conventional imaging device 50, such as a CMOS imager, having a conventional microlens 11 formed over a four transistor (4T) pixel cell 10. Wavelengths of incident light 1000 from a subject being imaged pass through the conventional microlens 11 formed on a material layer 30. The material layer 30 is formed over a color filter 17. Alternatively, the microlens 11 may be formed directly on the color filter 17. Each color filter 17 allows predominantly light of a respective specific color to pass through to a photosensor 12. A color is defined to be light having a specific range of wavelengths. Typical color filters include red, green, and blue filters (RGB), or cyan, magenta, and yellow (CMY) filters.

The photosensor 12 has a p-type region 12a and an n-type region 12b in a p-type epitaxial layer 14, which may be formed over a p-type substrate. The pixel cell 10 includes the photosensor 12, which may be implemented as a pinned photodiode, transfer transistor gate 16, floating diffusion region 18, reset transistor gate 22, source follower transistor gate 24 with associated source/drain regions, and row select transistor gate 26 with associated source/drain regions. The photosensor 12 is electrically connected to the floating diffusion region 18 by the transfer transistor gate 16 when the transfer transistor gate 16 is activated by a transfer gate control signal TX.

The reset transistor having a gate 22 is connected between the floating diffusion region 18 and a pixel supply voltage (e.g., Vaa-pix) line 31, coupled to a source/drain region 25. A reset control signal RST is used to activate the reset transistor gate 22, which resets the floating diffusion region 18 to the pixel supply voltage Vaa-pix level as is known in the art. The source follower transistor gate 24 is connected to the floating diffusion region 18 by a charge transfer line 23. The source follower transistor gate 24 converts the charge stored at the floating diffusion region 18 into an electrical output voltage signal. The row select transistor gate 26 is controllable by a row select signal SEL for selectively connecting the source follower transistor gate 24 and its output signal voltage to a column line 28 of a pixel array. The pixel cell 10 typically outputs a reset voltage Vᵣₛₜ, produced by the source follower transistor 24 after the floating diffusion region 18 is reset and an image signal V_{sig} after charge is transferred from the photosensor 12 to the floating diffusion region 18.

Although the imaging device 50 of FIG. 1 works well, there are several disadvantages associated with conventional microlenses (e.g., microlens 11). Conventional microlenses are typically formed by patterning blocks of microlens precursors over the photosensor, and then heating the entire package such that the blocks of microlenses melt and form hemi-spherical shapes based on the surface tension of the materials. However, the heating of the precursors to form conventional microlenses makes it difficult to ensure that the microlens maintains proper alignment and focuses light only on the photosensor 12 and not elsewhere on the pixel structure If misalignment does occur, the microlens 11 will focus light, at least in part, on to the circuitry of the pixel cell 10 rather than the photosensor 12, resulting in noise within the circuitry. In addition, the misalignment will increase the amount cross-talk between pixel cells, resulting in poor image quality.

Because the conventional methods of making the conventional microlenses (e.g., microlens 11 (FIG. 1)) rely heavily on the surface tension of the material to form the hemi-spherical shape, the materials that can be used must possess certain properties to form the necessary shapes. These materials are typically expensive, which increases the overall cost of manufacturing conventional imager packages.

In addition, the size of the overall imager is limited by the size of the microlens 11. Conventional microlenses are typically based on geometric focusing (e.g., the micro lenses are typically concave or convex to focus light onto the photosensor). The overall size limitations of conventional microlenses limit the scalability of the overall imaging device 50.

Finally, the heating of the overall package after the microlens precursor has been patterned over the photosensor could potentially damage the internal circuitry of the pixel cell and external circuitry of the overall package.

Accordingly, it is desirable to develop an imaging device that reduces the potential misalignment of a microlens over the photosensor; reduces or mitigates the amount of noise within a pixel cell; reduces or mitigates the amount of cross-talk; reduces the overall size of the imager package; and reduces the potential of harming the internal circuitry of the pixel cell.

### BRIEF SUMMARY OF THE INVENTION

The invention provides an imaging device having a pixel cell with a transparent structure capable of shifting the phase of a portion of the light incident on a pixel. Light designed to reach the photosensor is mixed with phase shifted light in pixel regions outside the photosensor, thereby reducing noise within a pixel cell, and also reducing the amount of cross-talk between pixel cells. The invention also relates to the formation of the pixel cell having the transparent structure.

### BRIEF DESCRIPTION OF THE DRAWINGS

The above-described features and advantages of the invention will be more clearly understood from the following detailed description, which is provided with reference to the accompanying drawings in which:

FIG. 1 illustrates a partial cross-sectional representation of a conventional imaging device;

FIG. 2 illustrates a partial cross-sectional representation of an imaging device constructed in accordance with a first exemplary embodiment of the invention;

FIGS. 3-6 illustrate partial cross-sectional representations of different stages of the fabrication of a plurality of FIG. 2 imaging devices;

FIG. 7 illustrates a partial cross-sectional representation of an imaging device constructed in accordance with a second exemplary embodiment of the invention;

FIG. 8 illustrates a partial cross-sectional representation of an imaging device constructed in accordance with a third exemplary embodiment of the invention;

FIG. 9 illustrates a partial cross-sectional representation of an imaging device constructed in accordance with a fourth exemplary embodiment of the invention;

FIG. 10 illustrates a partial cross-sectional representation of an imaging device constructed in accordance with a fifth exemplary embodiment of the invention;

FIG. 11 illustrates a block diagram of a CMOS imager incorporating imaging device constructed in accordance with FIG. 2; and

FIG. 12 illustrates a schematic diagram of a processor system incorporating the CMOS imager of FIG. 11 in accordance with an exemplary embodiment of the invention.

### DETAILED DESCRIPTION OF THE INVENTION

As used herein, the terms “semiconductor substrate” and “substrate” are to be understood to include any semiconductor-based structure. The semiconductor structure should be understood to include silicon, silicon-on-insulator (SOI), silicon-on-sapphire (SOS), silicon-germanium, doped and undoped semiconductors, epitaxial layers of silicon supported by a base semiconductor foundation, and other semiconductor structures. The semiconductor need not be silicon-based. The semiconductor could be germanium or gallium arsenide. When reference is made to the semiconductor substrate in the following description, previous process steps may have been utilized to form regions or junctions in or over the base semiconductor or foundation.

The term “pixel cell,” as used herein, refers to a photo-element unit cell containing a photosensor for converting photons to an electrical signal. For purposes of illustration, a single representative pixel and its manner of formation may be illustrated in the figures and description herein; however, typically fabrication of a plurality of like pixels proceeds simultaneously.

In the following description, the invention is described in relation to a CMOS imager for convenience; however, the invention has wider applicability to any photosensor of any imager cell, including, but not limited to, a charge coupled device (CCD).

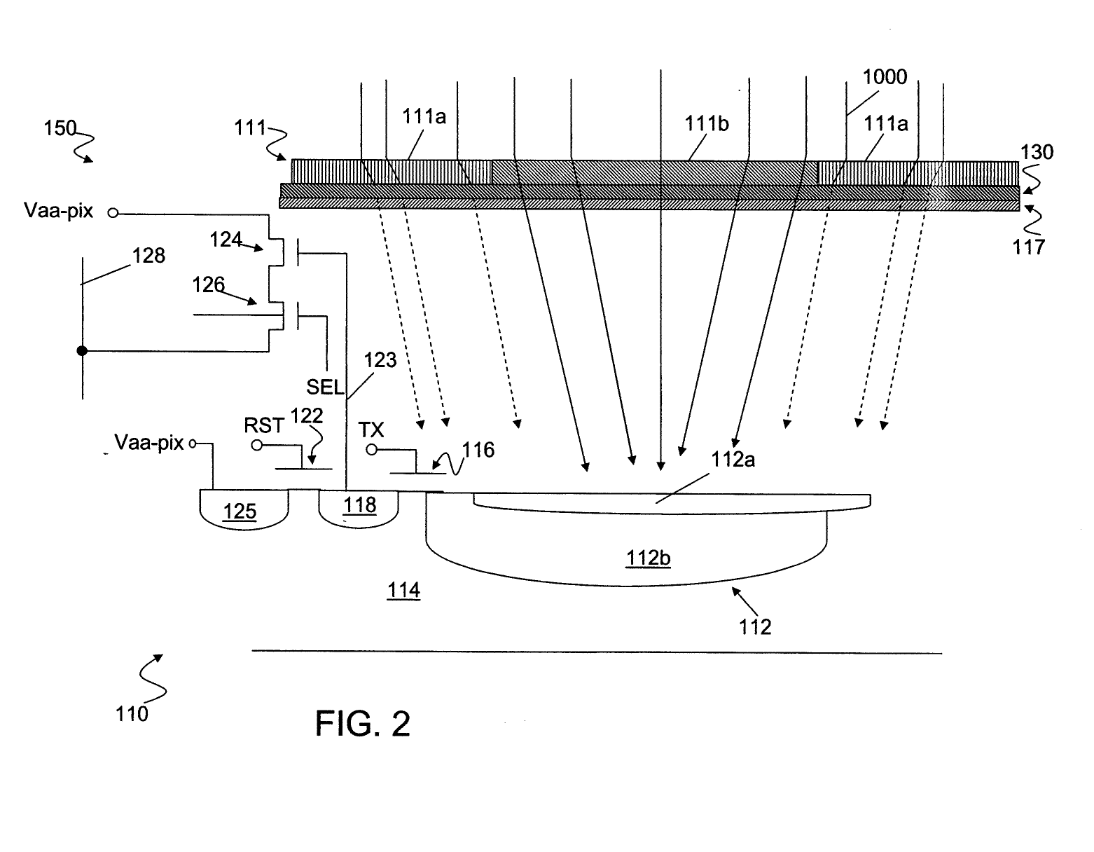

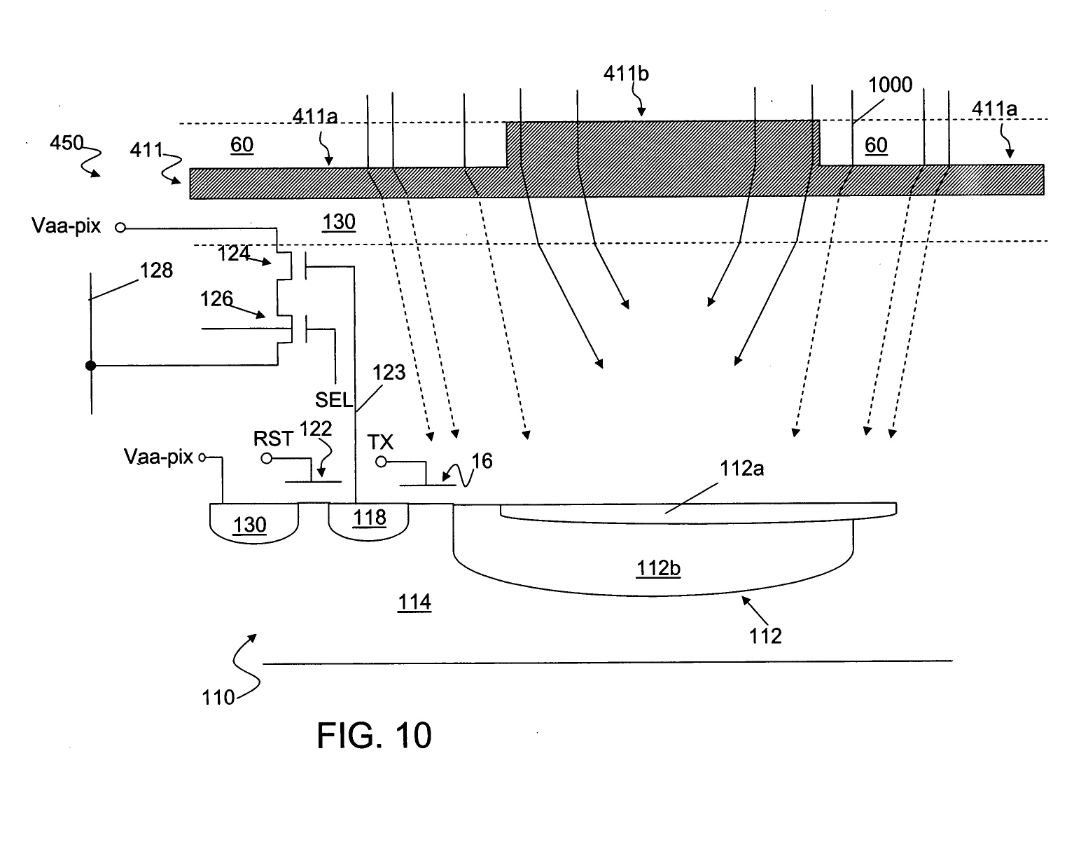

Referring now to FIG. 2, a representational partial schematic and cross-sectional view of an imaging device 150 constructed in accordance with an exemplary embodiment of the invention is illustrated. The imaging device 150 has a transparent structure 11 formed over a pixel cell 110. The FIG. 2 pixel cell 110 has a photosensor 112 that includes a p-type region 112a and an n-type region 112b in a p-type epitaxial substrate 114, transfer transistor gate 116, floating diffusion region 118, reset transistor gate 122 and associated source/drain region 125, source follower transistor gate 124 with associated source/drain regions, row select transistor gate 126 with associated source/drain regions, and a column line 128 that is coupled to readout circuitry, as discussed below with respect to FIG. 10.

The imaging device 150 also illustrates a color filter 117 formed over the pixel cell 110. Although not necessary, the illustrated imaging device 150 also has a material layer 130 formed over the color filter. The material layer 130 is typically formed of nitride or polyimide. Significantly, the FIG. 2 imaging device 150 has a transparent structure 111 over the pixel cell 110 including, but not limited to, over the photosensor 112.

The transparent structure 111 has a periodic array of alternating first and second areas 111a, 111b, which have different optical properties. In operation, incident light 1000 striking the first and second areas 111a, 111b will refract due to the properties of the materials forming the transparent structure 111. The phase of the wavelengths of incident light 1000 that passes through the first area 111a is phase shifted so that the wavelengths of incident light 1000 becomes out of phase by 180° (e.g., Δ=λ/2) (represented by the dashed lines) relative to a wavelengths of incident light that passes through the second area 111b (e.g., Δ=0) (represented by the solid lines). The wavelengths of incident light passing through the first area 111a produces a wavelength 180° out of phase, which can be destructively added to a wavelength that passes through the second area 111b, and thereby have a canceling effect at areas of the pixel cell outside of the photosensor 112 area. The incident light 1000 striking the substrate 114, therefore, is better localized on to the photosensor 112.

By using wavelengths of incident light that is phase shifted by 180° relative to wavelengths of incident light having no phase shift, and thereby destructively combining the wavelengths of incident light at areas outside the photosensor 112, the transparent structure 111 reduces or substantially mitigates the amount of cross-talk between pixel cells, and reduces the noise associated with incident light striking the pixel circuitry.

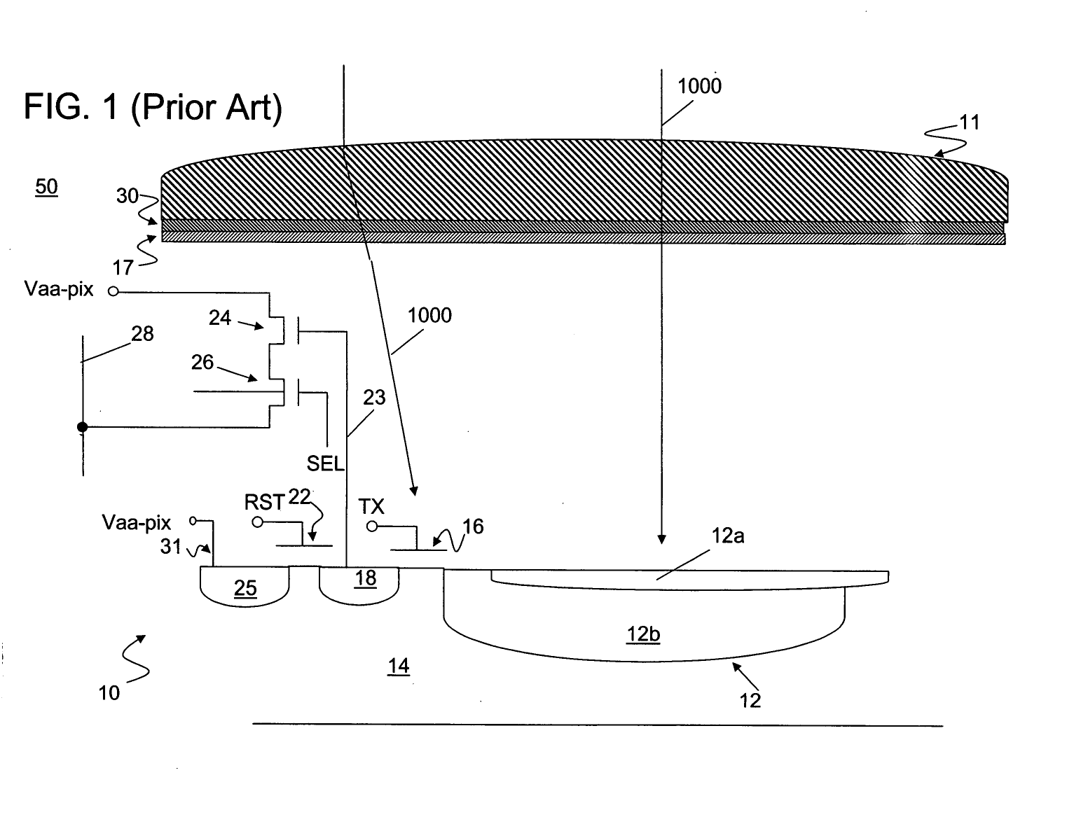

The transparent structure 111 may also address the size limitations of the overall imaging device 150 because the transparent structure 111 may be made thinner as compared to conventional microlenses (e.g., microlens 11 (FIG. 1)). Additionally, the transparent structure 111 can be formed as a flat layer, thereby simplifying processing steps.

The transparent structure 111 may be formed of any transparent materials, and/or configuration of such materials, capable of producing phase-shift properties. For example, the first and second areas 111a, 111b of the transparent structure 111 could be formed of materials selected from the group consisting of glass, for example, zinc selenide (ZnSe), boro-phosphosilicate glass (BPSG), phosphosilicate glass (PSG), borosilicate glass (BSG), silicon oxide, silicon nitride, or silicon oxynitride; an optical thermoplastic material such as tantalum pentoxide (Ta₂O₅), titanium oxide (TiO₂), polymethylmethacrylate, polycarbonate, polyolefin, cellulose acetate butyrate, or polystyrene; a polyimide; a thermoset resin such as an epoxy resin; a photosensitive gelatin; or a radiation curable resin such as acrylate, methacrylate, urethane acrylate, epoxy acrylate, polyester acrylate; or chrome oxide; quartz, or molybdenum silicide.

It is also not necessary that area 111b produce a 0° phase shift and area 111a produce a 180° phase shift. The materials forming the first and second areas 111a, 111b may also be selected and/or configured such that the first area 111a has phase shifting properties that phase shift a wavelength of incident light 180° relative to a wavelength of incident light passing through the second area 111b. For example, if a material for the first area 111a is selected such that wavelengths of incident light passing through a first area 111a could be phase shifted by 90°, a material that phase shifts wavelengths of incident light by 270° should be selected and/or configured for the second area 111b.

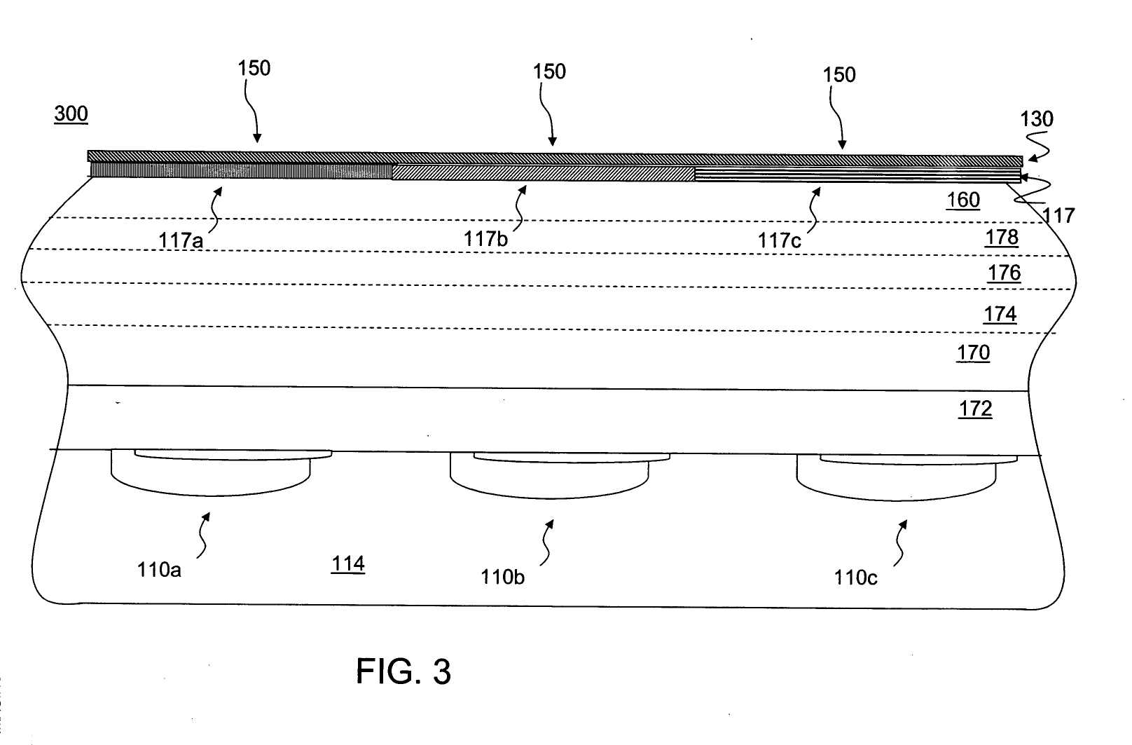

FIGS. 3-6 illustrate an exemplary method of fabricating an imaging device array 300 of the FIG. 2 imaging device 150. The imaging device array 300 has a color filter array 117 having a red, green, and blue color filter 117a, 117b, 117c over corresponding red, green, and blue pixel cells 110a, 110b, 110c, as illustrated in FIG. 3. The imaging device array 300 also has an optional material layer 130 formed over the color filter array 117.

The substrate 114 has an associated photosensor 112, and pixel circuitry (e.g., the FIG. 2 transfer transistor gate 116, floating diffusion region 118, reset transistor gate 122, and source/drain region 125). Other material layers which may be conventionally employed between the photosensors 110a, 110b, 100c and color filters 117a, 117b, 117c are illustrated as 170, 172, 174, 176, 178.

An upper passivation layer 160 can be formed over layer 178. The passivation layer 160 is typically planarized to create a substantially flat surface. The passivation layer 160 can be planarized by chemical mechanical polishing. The passivation layer 160 is typically formed of Tetraethyl Orthosilicate, Si(OC₂H₅)₄ (TEOS).

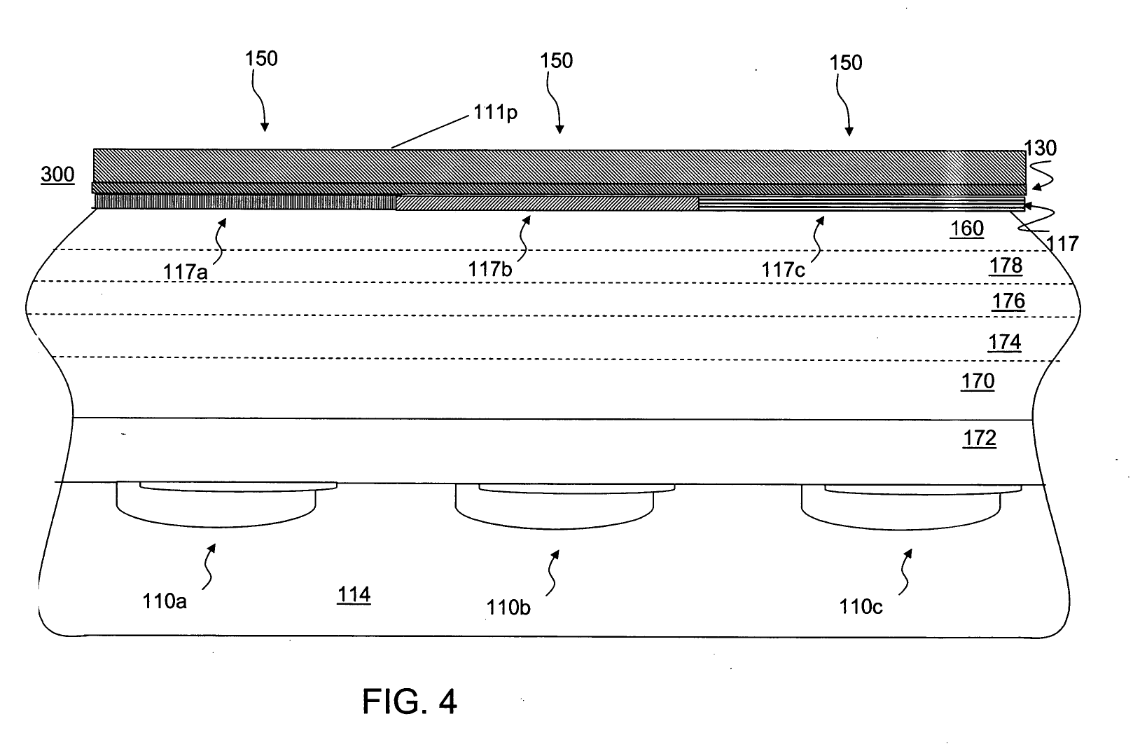

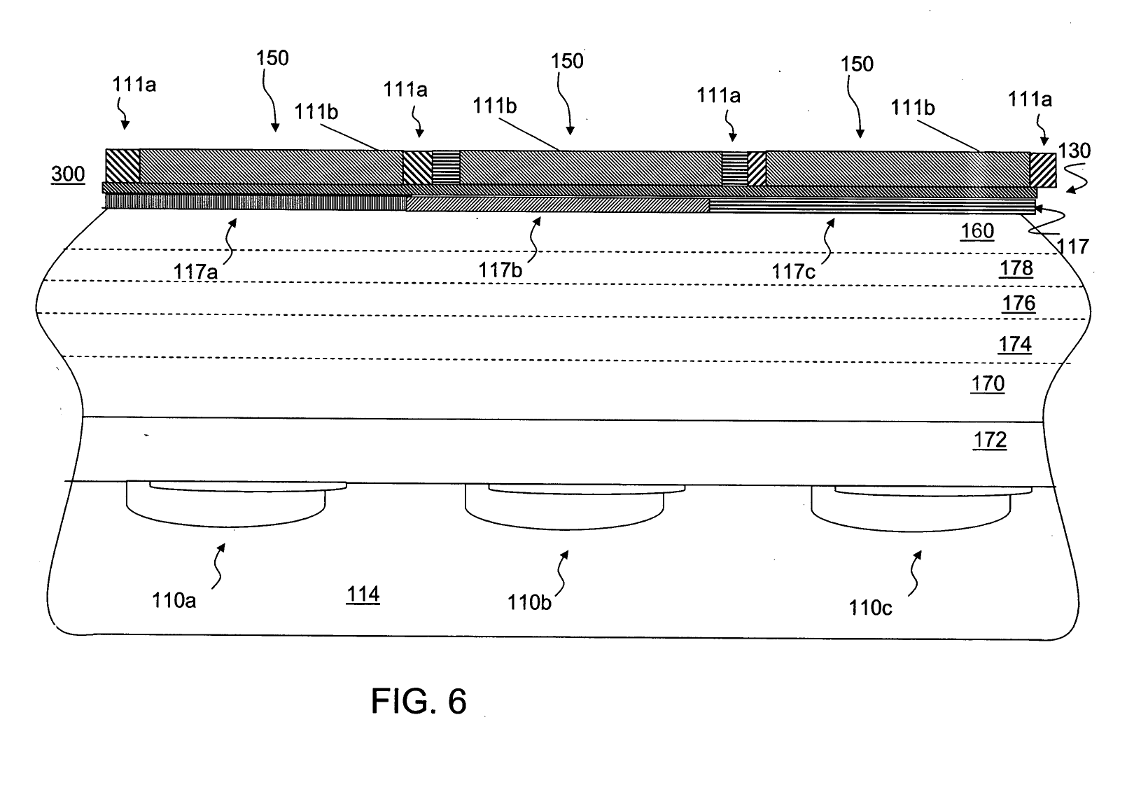

FIG. 4 illustrates the formation of a transparent structure precursor 111p over the material layer 130 of the imaging device array 300. The transparent structure precursor 111p can be deposited by known spin coating methods, although the formation of the transparent structure precursor 111p is not limited to spin coating. Once deposited, the transparent structure precursor 111p could be planarized by chemical mechanical polishing to create a planar surface. The transparent structure precursor 111p could be planarized to achieve a desired thickness, as discussed below with respect to FIG. 6.

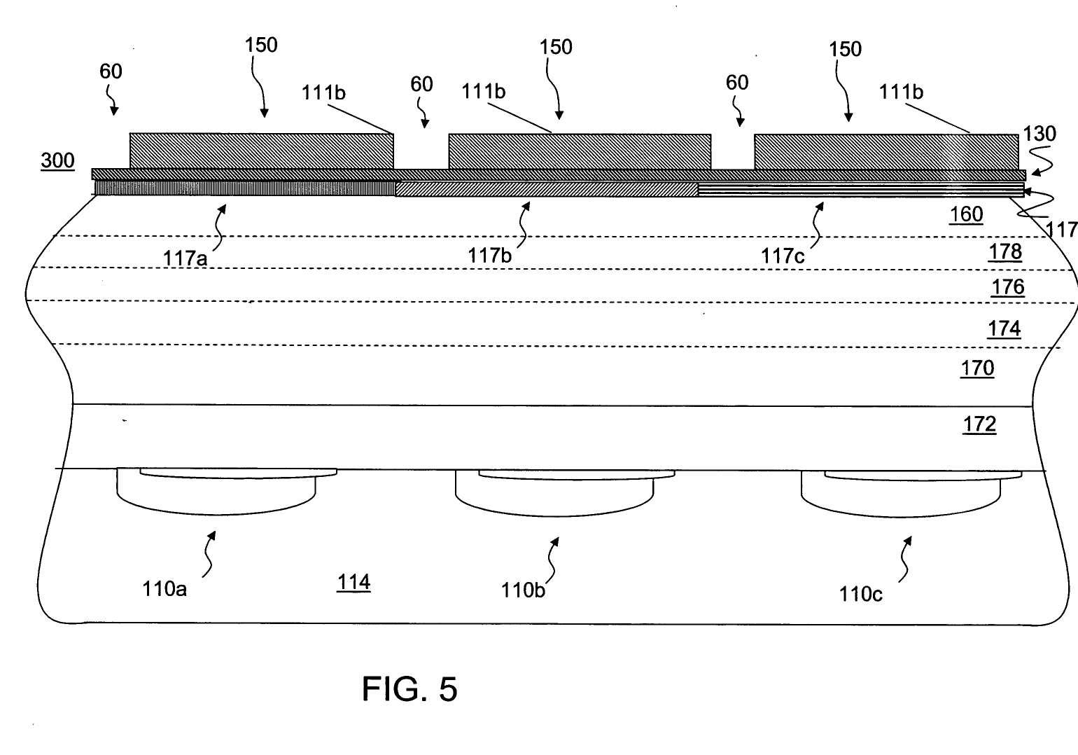

FIG. 5 illustrates recesses 60 formed within the transparent structure precursor 111p to create the second area 111b of the transparent structure 111 (FIG. 2). The recesses 60 are formed in locations where light passing there-through will be incident on the circuitry of the pixels 110a, 110b, 110c of the imaging device array 300 and not the photosensors.

The recesses 60 are filled with material in order to create the first areas 111a (FIG. 2) of the transparent structure 111 (FIG. 2), as discussed below with respect to FIG. 6. The recesses 60, therefore, must be tailored to have a distance (or gap) between each recess 60 such that the first areas 111a (FIG. 6) of the transparent structure 111 (FIG. 6) over each of the pixel cells 110a, 110b, 110c phase shift a wavelength of incident light by 180° relative to a wavelength of incident light passing through the second area 111b. The distance between the recesses 60 within which the first areas 111a (FIG. 6) are formed could be constant, or varied, depending on the application. The distance between the recesses 60 also depends on the thickness of the transparent structure precursor 111p, the wavelength of the color that the pixel cell 110 is intended to capture, and the length and shape of the pixel cell and photosensor.

For example, the distance (or gap) between two recesses 60 for a green pixel cell having a length of 2.2 μm, a transparent structure 111 having a thickness of 0.46 μm would typically be 0.8 μm. The actual distance between the recesses that form the first area 111a would also depend on the index of refraction for the material that comprises the first area 111a. The above described example is described based on the first area 111a being formed of a material having an index of refraction equal to 1.6, and a second area 111b having an index of refraction equal to 1.0.

FIG. 6 illustrates the recesses 60 (FIG. 5) filled with a material to form the first area 111a of the transparent structure 111. The FIG. 6 imaging device array 300 has red, green, and blue pixel cells 110a, 110b, 110c. The first and second areas 111a, 111b of each transparent structure 111 over each color pixel cell 110a, 110b, 110c is tailored to have a specific index of refraction such that a wavelength of incident light passing through the first area 111a is phase shifted by 180° relative to a wavelength of incident light passing through the second area 111b.

For example, the first area 111a of the transparent structure 111 could be comprised of a material in accordance with equation 1:
N−1=λ/2t (1)
where, N represents the refractive index of the material through which the wavelength passes, λ represents the wavelength of incident light of a particular color, and t represents the thickness of the material through which a wavelength must travel. For example, if the thickness (t) is constant at 0.46 μm, and the wavelength (λ) of the color green that equals 550 nm, the index of refraction of the material used for the first area 111a should be about 1.6. Therefore, any material having an index of refraction equal to about 1.6 can be used to phase shift the wavelength by 180°. The first and second areas 111a, 111b of each transparent structure 111 would be similarly tailored depending on which color the transparent structure 111 is designed to phase shift. Therefore, the materials that are used to fill the recesses 60 (FIG. 5) must be selected for each individual color, as illustrated in FIG. 6.

It should be noted that the above described example does not take into account any phase shift that may occur in the second area 111b of the transparent structure 111. For example, if the second area 111b imparts any phase shift of incident light, the materials used for the first area 111a should be tailored such that wavelengths of incident light that pass through the first area 111a are phase shifted 180° relative to wavelengths of incident light passing through the second area 111b.

The fabrication of the transparent structure 111 is nearly complete, although additional material layers may be formed over the imaging device array 300. For example, a material layer could be formed over the imaging device array 300 to protect the transparent structure 111. In addition, the material layer could be planarized for better handling during subsequent processing steps.

The fabrication of the imaging device array 300 having a transparent structure 111 over the pixel cells 110a, 110b, 110c illustrated in FIGS. 3-6 reduces the potential for misalignment because the etching process can be better controlled than the heating process and hemi-spherical formation of the FIG. 1 conventional microlens 11. In addition, the internal circuitry of the pixel cells 110a, 110b, 110c of the imaging device array 300 is less prone to heat damage because the formation of the transparent structures 111 does not necessarily have to go through heat processing. It should be noted, however, that certain applications may require that the transparent structure 111 have a substantially hemi-spherical or hemi-elliptical shape, which may require heat processing. Although the materials used in forming the transparent structure 111 would be limited to those of conventional microlenses, the transparent structure 111 would still be advantageous for reducing the amount of incident light striking the circuitry, and decreasing the amount of cross-talk between pixel cells.

It should be noted that FIGS. 3-6 illustrate only one method of making the transparent structure 111 over the pixel cell array 300, and the illustrations are not limiting in any way.

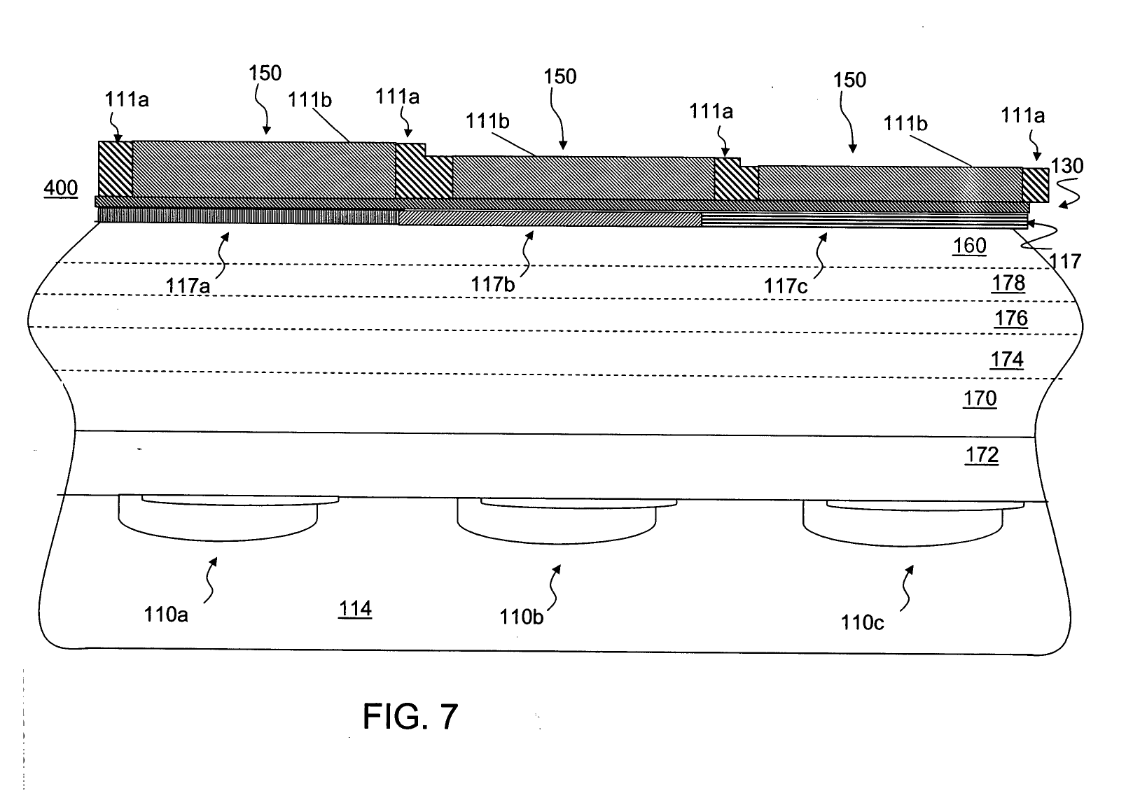

FIG. 7 illustrates an imaging device array 400 constructed in accordance with a second exemplary embodiment of the invention. In contrast to FIG. 6, which illustrates different materials comprising the first areas 111a of a transparent structure 111 for each different color, FIG. 7 illustrates a transparent structure over each of the pixel cells 110a, 110b, 110c wherein the materials are the same and the thickness is varied in accordance with equation 1, discussed above with respect to FIG. 6. Although, the materials used for each of the first areas 111a of the transparent structure 111 is selected from the same material, the thickness over each pixel cell 110a, 110b, 110c is tailored such that the wavelengths of incident light passing through the first area 111a is phase shifted 180° relative to wavelengths of incident light passing through the second area 111b.

The FIG. 7 imaging device array 400 is made in substantially the same way as the FIG. 6 imaging device array 300; the materials used for the first areas 111a are the same. The transparent structures 111 are selectively etched to produce a thickness over each of the pixel cells 110a, 110b, 110c specifically tailored to the color of incident light the pixel cells 110a, 110b, 110c are designed to capture, in accordance with equation 1 as discussed above with respect to FIG. 6.

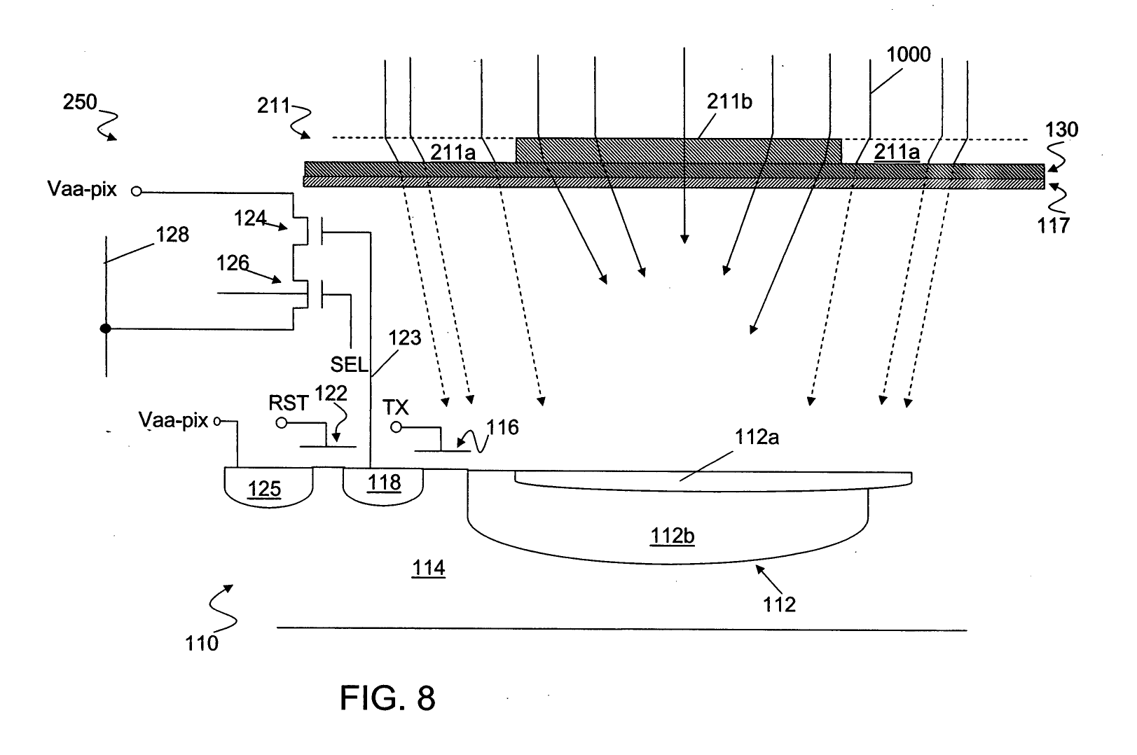

FIG. 8 illustrates an imaging device 250 constructed in accordance with a third exemplary embodiment of the invention. The imaging device 250 has a transparent structure 211 formed over a pixel cell 110. For the sake of clarity, many of the material layers discussed above with respect to FIGS. 3 and 4 have been omitted. The transparent structure 211 of FIG. 8 has first and second areas 211a, 211b. The first area 211a of the transparent structure 211 is formed of air. Like the FIG. 2 transparent structure 111, the FIG. 8 transparent structure 211 reduces or substantially mitigates the amount of incident light that strikes the circuitry of the pixel cell 110. Wavelengths of incident light passing through the second area 211b are phase shifted by 180° relative to wavelength that passes through the first area 211a, thereby having a canceling effect at areas of the pixel cell outside of the photosensor 112 area.

The FIG. 8 imaging device 250 can be fabricated by the method discussed above with respect to FIGS. 3-6. One difference, however, would be that the recesses 60 (FIG. 5) would not be filled with a material, as discussed above with respect to FIG. 6. Therefore, the material used to form the second area 211b of the transparent structure 211 should be selected from a material that can phase shift a wavelength of incident light such that the wavelength is out of phase 180° relative to a wavelength of incident light that passes through the first area 211a (e.g. air).

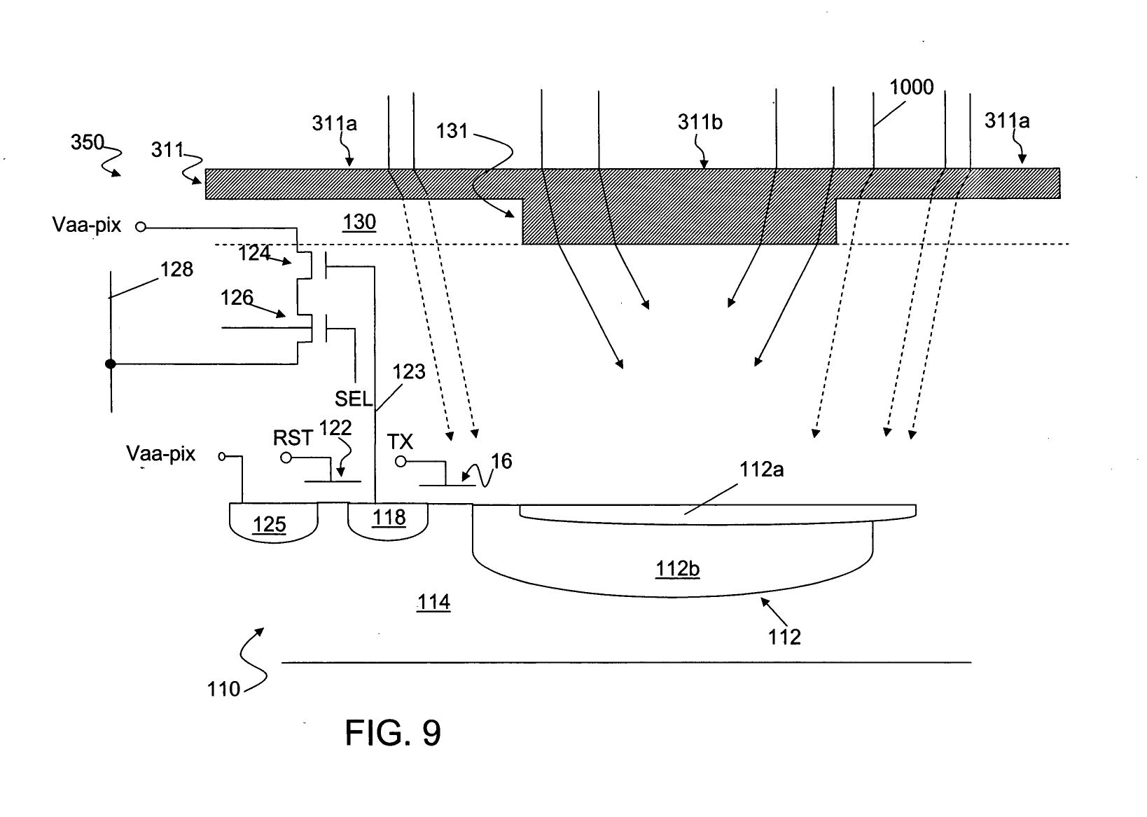

FIG. 9 illustrates an imaging device 350 constructed in accordance with a fourth exemplary embodiment of the invention. For the sake of clarity, the color filter 117 has been omitted from the illustration. It should be recognized that the color filter 117 and other material layers discussed above with respect to FIGS. 3 and 4 are typically formed underneath a transparent structure 311 of the imaging device 350.

The transparent structure 311 having first and second areas 311a, 311b is provided over the pixel cell 110. The first and second areas 311a, 311b have different thicknesses, such that wavelengths of incident light in the form of photons 1000 passing through the first area 311a are phase shifted by 180° (e.g., Δθ=λ/2) (represented by the dashed lines) relative to a wavelengths of incident light that pass through the second area 311b (e.g., Δθ=0) (represented by the solid lines), thereby having a canceling effect, and reducing or mitigating the amount of incident light striking the circuitry of the pixel cell 110.

The first and second areas 311a, 311b of the transparent structure 311 can be formed of any of the materials discussed above with respect to FIG. 2. The illustrated transparent structure 311 has first and second areas 311a, 311b that are formed of the same material, but the illustration is not intended to be limiting in any way. For example, the first and second materials 311a, 311b could be formed of materials that are different.

If the materials comprising the first and second areas 311a, 311b are substantially the same, the thickness of the materials should be varied in accordance with equation 1, as discussed above with respect to FIG. 6.

The FIG. 9 transparent structure 311 could be formed in a substantially similar fashion as the FIG. 6 transparent structure. However, in fabricating the FIG. 9 transparent structure 311, trenches 131 are etched into the material layer 130. A transparent structure precursor is then formed over the material layer 130 and over and within the trench 161, as illustrated in FIG. 9. The transparent precursor structure can then be planarized to a desired thickness, in accordance with equation 1, as discussed above with respect to FIG. 6. The transparent structure precursor could be planarized by chemical mechanical polishing.

FIG. 10 illustrates an imaging device 450 constructed in accordance with a fifth exemplary embodiment of the invention. Similar to the FIG. 9 imaging device 350, the FIG. 10 imaging device 450 illustrates a transparent structure 411 having first and second areas 411a, 411b over the pixel cell 110. The first and second areas 411a, 411b have different thicknesses, such that wavelengths of incident light in the form of photons 1000 that pass through the first area 411a are phase shifted by 180° (e.g., Δθ=λ/2) (represented by the dashed lines) relative to wavelengths of incident light that pass through the second area 411b, thereby having a canceling effect. Like the FIG. 9 imaging device 350, the FIG. 10 imaging device 450 reduces the amount of incident light 1000 striking the circuitry of the pixel cell 110.

The FIG. 10 imaging device 450 can be formed in substantially the same manner as the FIG. 6 imaging device array 300. The transparent structure precursor over the passivation layer 160 is fabricated as a flat surface similar to the fabrication process illustrated in FIG. 4. In contrast to FIG. 5, which illustrates trenches 60 that reach the material layer 130, the trenches 60 formed in the FIG. 10 transparent structure precursor do not extend to the material layer 130. Although, the first and second areas 41a, 411b are illustrated as being formed of the same material, but the illustration is not limiting in any way. For example, the materials forming the first and second areas 411a, 411b could be different.

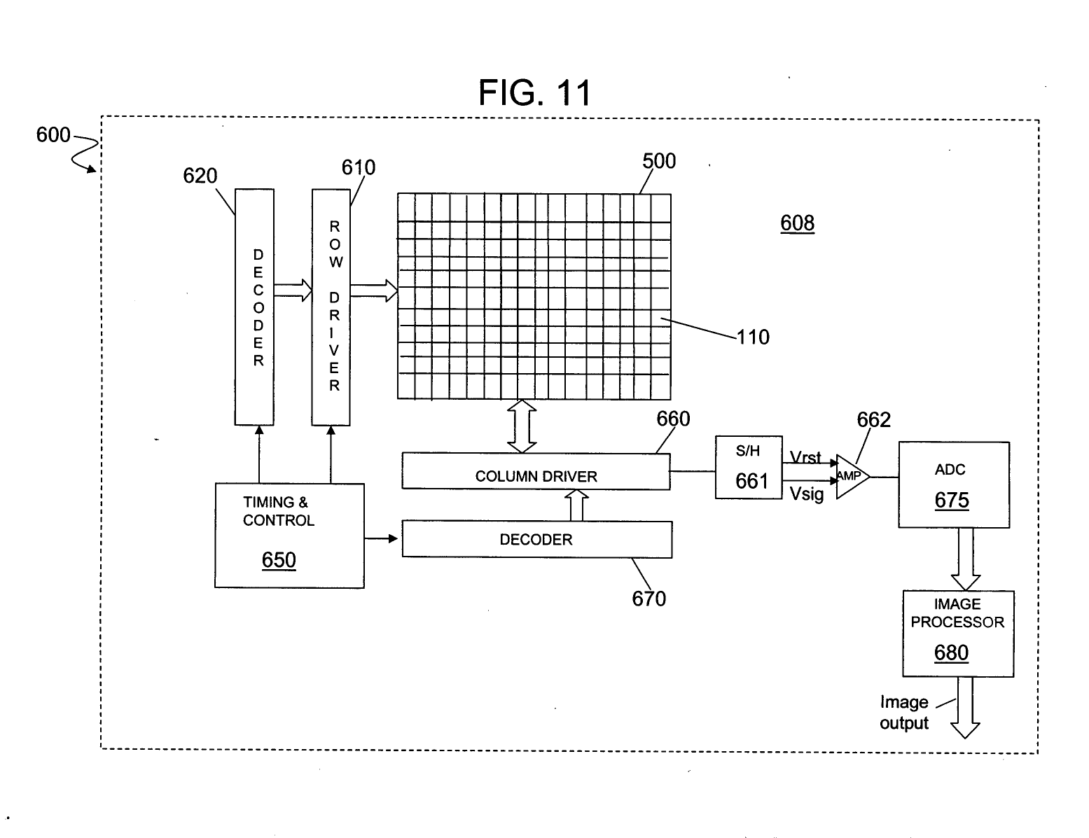

FIG. 11 illustrates a CMOS imager incorporating an imaging device array 500 having pixel cells 110 using a lens structure in accordance with the invention. The pixel cells 110 of each row in the imaging device array 500 are all turned on at the same time by a row select line, and the pixel cells of each column are selectively output by respective column select lines. A plurality of row and column lines are provided for the entire array 500. The row lines are selectively activated in sequence by the row driver 610 in response to row address decoder 620 and the column select lines are selectively activated in sequence for each row activation by the column driver 660 in response to column address decoder 670. Thus, a row and column address is provided for each pixel cell 110. The CMOS imager is operated by the control circuit 650, which controls address decoders 620, 670 for selecting the appropriate row and column lines for pixel readout, and row and column driver circuitry 610, 660 which apply driving voltage to the drive transistors of the selected row and column lines.

The pixel output signals typically include a pixel reset signal Vᵣₛₜ taken off of the floating diffusion region (via the source follower transistor) when it is reset and a pixel image signal V_{sig}, which is taken off the floating diffusion region (via the source follower transistor) after charges generated by an image are transferred to it. The Vᵣₛₜ and V_{sig} signals are read by a sample and hold circuit 661 and are subtracted by a differential amplifier 662, which produces a difference signal (Vᵣₛₜ−V_{sig}) for each pixel cell 110, which represents the amount of light impinging on the pixel cell 110. This signal difference is digitized by an analog to digital converter 675. The digitized pixel signals are then fed to an image processor 680 to form and output a digital image. In addition, as depicted in FIG. 11, the CMOS imager device 608 may be included on a semiconductor chip (e.g., substrate 600).

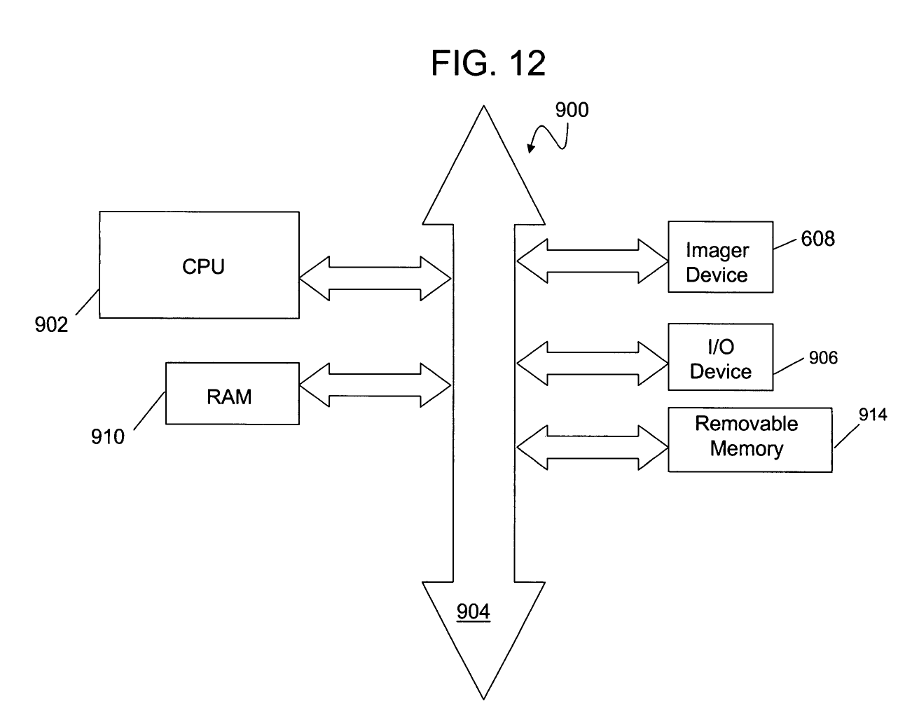

FIG. 12 shows a system 900, a typical processor system modified to include an imager device (such as the CMOS imager device 608 illustrated in FIG. 11) of the invention. The processor system 900 is exemplary of a system having digital circuits that could include image sensor devices. Without being limiting, such a system could include a computer system, camera system, scanner, machine vision, vehicle navigation, video phone, surveillance system, auto focus system, star tracker system, motion detection system, image stabilization system, and other systems employing an imager.

System 900, for example a camera system, generally comprises a central processing unit (CPU) 902, such as a microprocessor, that communicates with an input/output (I/O) device 906 over a bus 904. CMOS imager device 608 also communicates with the CPU 902 over the bus 904. The processor-based system 900 also includes random access memory (RAM) 910, and can include removable memory 914, such as flash memory, which also communicate with the CPU 902 over the bus 904. The CMOS imager device 608 may be combined with a processor, such as a CPU, digital signal processor, or microprocessor, with or without memory storage on a single integrated circuit or on a different chip than the processor.

It should again be noted that although the invention has been described with specific references to CMOS imaging devices (e.g., 150, 250, 350, 450, of FIGS. 2, 7, 8, and 9), the invention has broader applicability and may be used in any imaging apparatus. For example, the invention may be used in conjunction with charge coupled device (CCD) imagers. The above description and drawings illustrate preferred embodiments which achieve the objects, features, and advantages of the invention. Although certain advantages and preferred embodiments have been described above, those skilled in the art will recognize that substitutions, additions, deletions, modifications and/or other changes may be made without departing from the spirit or scope of the invention. Accordingly, the invention is not limited by the foregoing description but is only limited by the scope of the appended claims.

What is claimed as new and desired to be protected by Letters Patent of the United States is:

1. An imager, comprising:
a pixel cell formed in a substrate and having a photosensor area including charge accumulation region; and
a transparent structure over said pixel cell, said transparent structure having first and second areas, wherein one of said first and second areas is capable of shifting incident light relative to the other of said first and second areas such that light passing through said first and second areas are destructively canceled.

2. The imager cell of claim 1, wherein said first and second areas are such that said destructive cancellation occurs outside said photosensor area.

3. The imager cell of claim 1, wherein said relative phase shift is equal to about 180°.

4. The imager cell of claim 3, wherein said first area is capable of shifting incident light by 180°, and said second area is capable of allowing incident light to pass through to said photosensor without the phase shift.

5. The imager cell of claim 1, wherein said first and second areas are formed of the same material.

6. The imager cell of claim 1, wherein at least one of said first and second areas is formed of a material selected from the group consisting of zinc selenide (ZnSe), boro-phospho-silicate glass (BPSG), phosphosilicate glass (PSG), borosilicate glass (BSG), and silicon oxynitride.

7. The imager cell of claim 1, wherein at least one of said first and second areas is formed of a material selected from the group consisting of tantalum pentoxide (Ta₂O₅), titanium oxide (TiO₂), polymethylmethacrylate, polycarbonate, polyolefin, cellulose acetate butyrate, and polystyrene.

8. The imager cell of claim 1, wherein one of said first and second areas is formed of a gas.

9. The imager cell of claim 1, wherein one of said first and second areas is formed of BPSG.

10. The imager cell of claim 1, wherein one of said first and second areas is formed of quartz.

11. The imager cell of claim 1, wherein a thickness of said first area and a thickness of said second area are the same.

12. The imager cell of claim 1, wherein a thickness of said first area and a thickness of said second area are different.

13. An integrated circuit, comprising:
an array of photosensors formed in a substrate, each photosensor having an associated charge accumulation area; and
a transparent structure over said array of photosensors, said transparent structure having a periodic array of alternating first and second areas, wherein one of said first and second areas is capable of shifting a phase of a wavelength of incident light such that a phase shifted wavelength of the incident light destructively cancels a wavelength that passes through the other of first and second areas.

14. The integrated circuit of claim 13, wherein said phase shift is about 180° and substantially reduces the amount of incident light striking a surface of said substrate.

15. The integrated circuit of claim 13, wherein said first area is capable of shifting the phase of a first wavelength of incident light by 180°, and said second area is capable of allowing a second wavelength of incident light to pass through to said photosensor without shifting the phase of said second wavelength.

16. The integrated circuit of claim 13, wherein said first and second areas are formed of the same material.

17. The integrated circuit of claim 13, wherein one of said first and second areas is formed of air.

18. The integrated circuit of claim 13, wherein one of said first and second areas is formed of quartz.

19. The integrated circuit of claim 13, wherein a distance between two adjacent first areas is constant throughout said periodic array.

20. The integrated circuit of claim 13, wherein a thickness of said first area and a thickness of said second area are the same.

21. The integrated circuit of claim 13, wherein a thickness of said first area and a thickness of said second area are different.

22. A processor system, comprising:
a processor; and
an imager coupled to said processor, said imager comprising;
a pixel cell array, said pixel cell array having an array of photosensors formed in a substrate, each photosensor having an associated charge accumulation area, and
a transparent structure over said array of photosensors, said transparent structure having a periodic array of alternating first and second areas, wherein one of said first and second areas is capable of shifting the phase of incident light wavelengths such that the phase shifted wavelength cancels a wavelength passing through the other of said first and second areas.

23. The processor system of claim 22, wherein a distance between two first areas of said transparent structure is constant throughout said periodic array.

24. The processor system of claim 22, wherein a distance between two first areas is varied throughout the periodic array.

25. The processor system of claim 22, wherein a thickness of said first area and a thickness of said second area are the same.

26. A method of forming a pixel cell, comprising:
forming a photosensor in a substrate, said photosensor having a charge accumulation area; and
forming a transparent structure over said charge accumulation area of said pixel cell, said structure having first and second areas, wherein one of said first and second areas is capable of shifting a phase of a wavelength of incident light relative to a wavelength of incident light passing through the other of said first and second areas such that the wavelengths are capable of destructively canceling each other.

27. The method according to claim 26, wherein said step of forming a transparent structure is performed by:
planarizing a material layer over said photosensor;
forming a transparent structure precursor over said material layer; and
creating recesses within said transparent structure precursor.

28. The method according to claim 27, wherein said transparent structure precursor is selected from a material selected from the group consisting of tantalum pentoxide (Ta₂O₅), titanium oxide (TiO₂), polymethylmethacrylate, polycarbonate, polyolefin, cellulose acetate butyrate, and polystyrene.

29. The method according to claim 27, further comprising the step of filling said recesses with a second material.

30. The method according to claim 27, further comprising the step of planarizing said transparent structure precursor to a desired thickness before said step of forming recesses within said transparent structure precursor.

31. The method according to claim 26, further comprising the step of forming a color filter between said photosensor and said transparent structure.
